(19) United States
(12) Patent Application Publication
(10) Pub. No.: US 2005/0205949 A1
(43) Pub. Date: Sep. 22, 2005

(54) Semiconductor device having moving part

(75) Inventor: Masatoshi Tokunaga, Chiyu-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/063,857

(22) Filed: Feb. 24, 2005

(30) Foreign Application Priority Data
Mar. 18, 2004 (JP) 2004-78057

(51) Int. Cl. H01L 29/84

(52) U.S. Cl. 257/415

(57) ABSTRACT

A semiconductor device includes a semiconductor layer supported by a support substrate etched to form a moving part released from the support substrate. The moving part has a plurality of portions extending in directions different from each other. A plurality of through-holes is formed as slender holes elongated along a length direction of each of the portions in each of the plurality of portions.

### CROSS REFERENCE TO RELATED APPLICATION

This application is based upon, claims the benefit of priority of, and incorporates by reference the contents of, Japanese Patent Application No. 2004-78057 filed on Mar. 18, 2004.

### FIELD OF THE INVENTION

The present invention relates to a semiconductor device in which a semiconductor layer supported by a support substrate is etched to form a moving part released from the support substrate and, more particularly, to a semiconductor device having a plurality of through-holes formed in the moving part.

### BACKGROUND OF THE INVENTION

A semiconductor device in which a semiconductor layer supported by a support substrate is etched to form a moving part released from the support substrate has been disclosed, for example, in JP 2001-133268A (hereafter “patent document 1”). Here, an angular velocity sensor uses an SOI (silicon on insulator) substrate that is made by bonding two silicon substrates together via an oxide film.

This angular velocity sensor is a surface-worked type semiconductor device in which one of two silicon substrates in the SOI substrate is constructed as a support substrate and in which the other silicon substrate and the oxide film are subjected to a well-known micro-machining technology such as trench etching or sacrificial layer etching from the surface of the other silicon substrate to form a moving part on the other silicon substrate.

Further, in the semiconductor device of the surface-worked type like this, in order to increase the efficiency of etching and to reduce weight, a plurality of through-holes are made in a large area portion that is unetched such as a moving part. Such a device is disclosed in, for example, JP 2001-99861A (hereafter “patent document 2”).

In the semiconductor device having such a moving part, the moving part released from a support substrate is displaced in a horizontal plane along the layer plane of a semiconductor layer constructing the moving part. To be more specific, an angular velocity sensor or an accelerator sensor is formed in this manner.

Further, as described above, when a plurality of through-holes are made in the moving part, individual holes are rectangular and are arranged regularly in the related art. Further, since the size of an individual through-hole is determined by the efficiency of etching, although not said with certainty, the ratio of the width of the hole to the length of the hole and the width of the remaining portion between the holes is generally approximately equal to 1:3-6:1.

However, the study of the present inventors resulted in the discovery that there were cases where the moving part could not secure sufficient strength depending on the arrangement construction of the through-holes.

To be more specific, in the case of the above-described sensor having a moving part displaced in the horizontal plane, the moving part having strength reduced by the through-holes is easily deformed in a vertical direction, that is, in the direction of thickness of the semiconductor layer by the effect of gravity and the like.

Thus, the moving part is not displaced only two-dimensionally, but three-dimensionally, and behaves in a manner different from original designed. This results in failure to provide the desired displacement characteristics of the moving part and lower displacement detection efficiency. In other words, because the output of the sensor is varied by the deformation of the moving part caused by an external force, it is necessary to reduce the degree of insufficient strength of the moving part caused by the plurality of through-holes to the minimum.

### SUMMARY OF THE INVENTION

In view of the above problem, in a semiconductor device in which a semiconductor layer supported by a support substrate is etched to form a moving part released from the support substrate and in which a plurality of through-holes are formed in the moving part, it is an object of the present invention to lessen reduction in the strength of the moving part in the direction of thickness of the semiconductor layer to a minimum.

In order to achieve the above object, the present inventors investigated a variety of directions of arrangement of a plurality of through-holes each shaped like an elongated hole such as rectangular hole when forming the through-holes in a moving part.

As the results of investigation, it was found that when the through-holes are arranged in such a way that the length direction of the moving part is aligned with the length direction of the through-hole, the strength of the moving part in the direction of thickness of the semiconductor layer is greatly enhanced as compared with the strength of the moving part when the length direction of the moving part is perpendicular to the length direction of the through-hole. The invention has been made on the basis of this finding.

That is, according to a first aspect, there is provided a semiconductor device in which a semiconductor layer supported by a support substrate is etched to form a moving part released from the support substrate and in which a plurality of through-holes are formed in the moving part, characterized in that the moving part has a plurality of portions extending in directions different from each other and in that each of the plurality of through-holes is formed in a slender hole in each of the plurality of portions and is elongated along the length direction of each of the portions.

When the moving part has the plurality of portions extending in directions different from each other, when each of the plurality of through-holes is formed in a slender hole elongated along the length direction of each of the portions in each of the plurality of portions, the through-holes are arranged in each of the plurality of portions in such a way that the length direction of each of the portions is aligned with the length direction of each of the plurality of through-holes.

Hence, in the semiconductor device in which the semiconductor layer supported by the support substrate is etched to form the moving part released from the support substrate and in which the plurality of through-holes are formed in the moving part, a reduction in the strength of the moving part in the direction of thickness of the semiconductor layer can be lessened to a minimum.

Here, according to a second aspect, in the semiconductor device having the moving part as defined by the first aspect, the moving part can be displaced in a predetermined direction when a mechanical quantity is applied thereto.

Accordingly, the semiconductor device can be applied to a semiconductor mechanical quantity sensor for detecting a mechanical quantity such as angular velocity and acceleration.

### BRIEF DESCRIPTION OF THE DRAWINGS

The above and other objects, features and advantages of the present invention will become more apparent from the following detailed description made with reference to the accompanying drawings:

FIG. 1 is a schematic plan view of an angular velocity sensor in accordance with a preferred embodiment;

FIG. 2 is an enlarged plan view of an encircled portion of FIG. 1 indicated by II;

FIG. 3 is a schematic sectional view along a line III-III in FIG. 1;

FIG. 4 is an illustration to show a model when the length direction of a moving part is perpendicular to the length direction of through-hole;

FIG. 5 is an illustration to show a model when the length direction of a moving part is aligned with the length direction of through-hole; and

FIG. 6 is a graph to show the result obtained by analyzing the relationship between load applied to the moving part and the amount of displacement of its tip in FIG. 4 and FIG. 5.

### DETAILED DESCRIPTION OF THE PREFERRED EMBODIMENTS

Hereafter, the preferred embodiments of the invention, shown in the drawings will be described. In the present embodiment will be described an example in which a semiconductor device having a moving part of the invention is applied to an angular velocity sensor 100, although it is not intended to limit the invention to this angular velocity sensor 100.

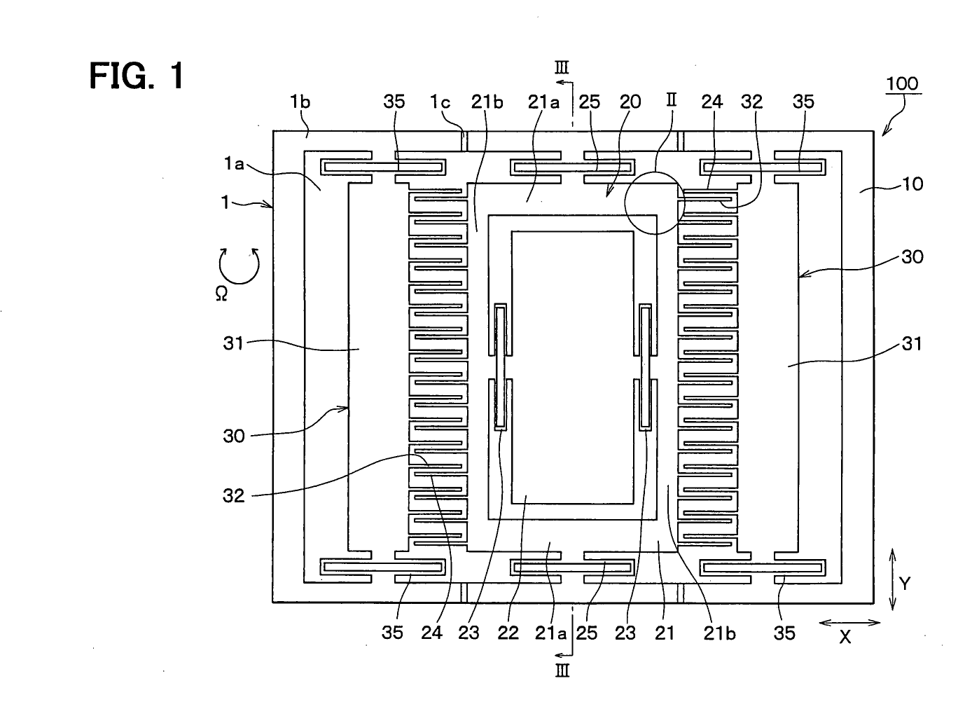

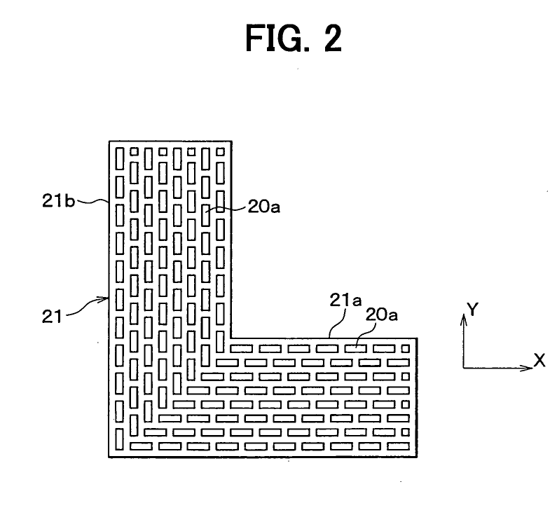

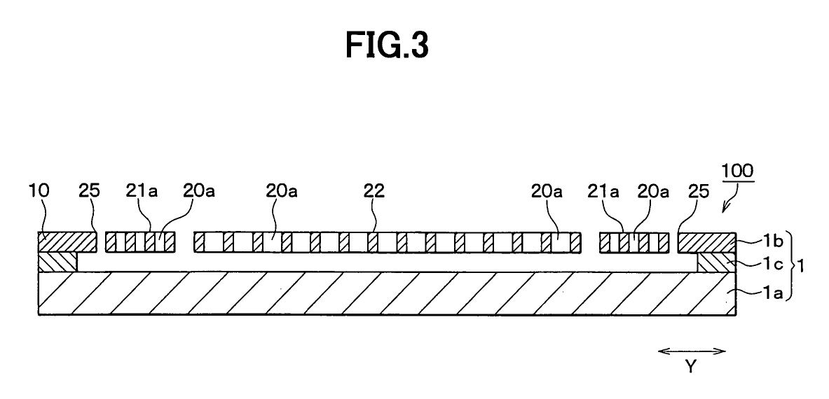

FIG. 1 is a schematic plan view to show the construction of an angular velocity sensor 100 in accordance with an embodiment of the invention and FIG. 2 is an enlarged plan view of an encircled portion of FIG. 1 indicated by II. FIG. 3 is a schematic sectional view along line III-III of FIG. 1.

The angular velocity sensor 100 is formed from a semiconductor substrate 1 made of a silicon substrate or the like.

To be more specific, as shown in FIG. 3, trenches are formed in this semiconductor substrate 1 by well-known semiconductor manufacturing technology such as etching, whereby a structural body is formed in which a frame-shaped base part 10, a moving part 20 and a detection part 30, both of which are located inside the periphery of a frame in the base part 10, are partitioned from each other.

Describing more specifically, as shown in FIG. 3, the angular velocity sensor 100 is formed by using, for example, an SOI (silicon on insulator) substrate 1, which is formed by bonding two silicon substrates 1a, 1b together via an oxide film 1c, as a semiconductor substrate 1.

One silicon substrate 1a of the two silicon substrates 1a, 1b in this SOI substrate 1 is constructed as a support substrate. The other silicon substrate 1b and the oxide film 1c are subjected to well-known micro-machining technology such as trench etching or sacrificial layer etching from the surface of the other silicon substrate 1b.

With this operation, the trenches are formed on the other silicon substrate 1b and the structural body including the parts 10 to 30 partitioned by the trenches is formed on the other silicon substrate 1b.

Referring to FIG. 1, the surface of the other silicon substrate 1b has the above-described structural body formed thereon, that is, the surface of the semiconductor layer 1b supported on the support substrate 1a. Further, as shown in FIG. 1 and FIG. 3, the oxide film 1c is removed in the inner peripheral portion of the base part 10 by sacrificial layer etching.

In this manner, inside the periphery of this base part 10, the other silicon substrate 1b having the above-described structural body formed thereon is separated from the one silicon substrate 1a, that is, the support substrate 1a.

In this example, the other silicon substrate 1b is supported in its base part 10 on the one silicon substrate 1avia the oxide film 1c, and the moving part 20 is released from the one silicon substrate 1a.

Here, as shown in FIG. 1, the moving part 20 includes a frame part 21 shaped like a rectangular frame, a weight part 22 located in this frame part 21 and shaped like a rectangle, and two vibration beams 23, each of which is shaped like a rectangular frame and couples the frame part 21 to the weight part 22.

The vibration beams 23 have an elastic function capable of expanding or contracting in the X direction shown in FIG. 1. The weight part 22 can be vibrated in the X direction with respect to the frame part 21 by these vibration beams 23. Further, a comb-teeth electrode 24 shaped like the teeth of a comb is formed on each of the sides opposed to, each other in the X direction in the outer periphery of the frame part 21.

Further, the frame part 21 is coupled to the base part 10 via detection beams 25 shaped like a rectangular frame in the outer periphery of the sides opposed to each other in the Y direction. This detection beam 25 has an elastic function capable of expanding or contracting in the Y direction shown in FIG. 1 and the weight part 22 and the frame part 21, that is, the moving part 20 can vibrate in the Y direction (the vibration of the moving part 20 in the Y direction can be detected).

Two detection parts 30 are provided on both sides in the X direction (in the lateral direction in FIG. 1) of the moving part 20. Each of the detection parts 30 includes a rectangular electrode weight 31 as a mass part in the detection part and a detection electrode 32 shaped like the teeth of a comb and protruding from the electrode weight 31 in the outer periphery of this electrode weight 31.

Here, the detection electrode 32 in the detection part 30 and the comb-teeth electrode 24 in the moving part 20 are arranged in such a manner that they are opposed to each other with gaps between them in the Y direction so as to be engaged with each other in the gaps of the teeth of the combs.

Further, the electrode weight 31 is coupled to the base part 10 via an electrode beam 35 shaped like a rectangular frame in the outer periphery of the sides opposed to each other in the Y direction. The electrode 35 has an elastic function capable of expanding and contracting in the Y direction shown in FIG. 1 and the electrode weight 31 (detection part 30) can be vibrated in the Y direction by the electrode 35.

Further, the angular velocity sensor 100 includes a vibration mechanism (not shown) using electrostatic force or electromagnetic force as driving means for driving and vibrating the weight part 22 in the X direction. The detection of angular velocity is performed in a state where the weight part 22 is driven and vibrated by this vibration mechanism.

When the weight part 22 in the moving part 20 is driven and vibrated in the X direction by the elastic force (spring force) of the vibration beam 23 and the driving force of the vibration mechanism and an angular velocity Ω is generated around an axis vertical to the surface of paper in FIG. 1, a Coriolis force is applied to the weight 22 in the Y direction.

The whole moving part 20 is displaced in the Y direction by the balance between the Coriolis force and the spring force of the detection beam 25 to change the gaps between the opposed portions of the comb-teeth electrode 24 and the detection electrode 32, which are opposed to each other in the Y direction.

The amount of change in this gap is detected as a change in the capacity between both the electrodes 24 and 32 via a wiring part (not shown) formed in the base part 10, whereby the angular velocity Ω described above is detected.

In this manner, in the angular velocity sensor 100, the moving part 20 and the detection part 30 can be vibrated in the Y direction by the spring functions of the detection beam 25 and the electrode beam 35, respectively. Further, in this embodiment, when acceleration (external acceleration) in the Y direction or having a component in the Y direction is applied to a vibration system (moving part vibration system) constructed of the moving part 20 and the detection beam 25 and a vibration system (detection part vibration system) constructed of the detection part 30 and the electrode beam 35, the moving part 20 and the detection part 30 are displaced similarly in the Y direction.

Thereby, even when the external acceleration is applied thereto, the detection part 30 is displaced in the Y direction in which the Coriolis force is applied thereto in the same way as the moving part 20. Hence, the external acceleration does not have effect on the amount of change in the gaps between the opposed portions of both the parts 20 and 30, that is, the opposed portions of the comb-teeth electrode 24 and the detection electrode 32. For this reason, it is possible to detect only the Coriolis force caused substantially by the angular velocity without undergoing the effect of the external acceleration.

In the angular velocity sensor 100 shown in FIG. 1, the above-described operation of detecting the angular velocity is similar to that of an angular velocity sensor disclosed in patent document 1. Hence, the mass part vibration system and the detection part vibration system that displace the moving part (mass party 20 and the detection part 30 in the same way in the Y direction when this external acceleration is applied thereto may be similar to the means described in patent document 1.

In the angular velocity sensor 100 like this, in this embodiment, as shown in FIGS. 2 and 3, a plurality of through-holes 20a are formed in the moving part 20. Here, the individual through-hole 20a can be formed in the same rectangular shape as the conventional through-hole described above and in the same size as the conventional through-hole.

Although these through-holes are omitted in FIG. 1, in the angular velocity sensor 100, the through-holes 20a are formed in the comparatively large-area portions. The through-holes 20a are not formed in the beams 23, 25, 35 and the comb-teeth parts 24, 32, which are left not-etched and are comparatively small in area. That is, the through-holes 20a are formed in the portions of the frame part 21, the weight part 22, and the electrode weight 31 inside the periphery of the base part 10.

As described above, the angular velocity sensor 100 can be manufactured in such a manner that one silicon substrate 1a in the SOI substrate 100 is constructed as a support substrate and that the trench etching or the sacrificial layer etching is performed to the surface of the other silicon substrate 1b to form a structural body such as the moving part 20 on the other silicon substrate 1b and to remove the oxide film 1c to release the moving part 20.

Hence, also in this embodiment, in order to increase the efficiency of etching in the angular velocity sensor 100 as a semiconductor device of the surface-worked type and to reduce the weight of the angular velocity sensor 100, a plurality of through-holes 20a are formed in the portions such as the moving part 20 that are unetched and have large area.

In this embodiment, the plurality of rectangular through-holes 20a are arranged in such a way that the length direction of the frame part 21, the weight part 22, and the electrode weight 31 is aligned with the length direction of the through-holes 20a.

Although this arrangement of the through-holes 20a is not shown for the weight part 22 and the electrode weight 31 in FIG. 1, the Y direction in FIG. 1 is the length direction of the weight part 22 and the electrode weight 31, and the plurality of through-holes are arranged in the weight part 22 and the electrode weight 31 in such a way that this Y direction is aligned with the length direction of the individual through-holes.

Here, as shown in FIG. 1 and FIG. 2, the frame part 21 of the moving part 20 includes a plurality of portions 21a and 21b extending in the directions different from each other. That is, the frame part 21 includes the first portion 21a extending in the X direction in the drawing and the second portion 21b extending in the Y direction.

As shown in FIG. 2, each of the plurality of through-holes 20a in each of the first portion 21a and the second portion 21b in the frame part 21 is formed in the shape of a slender hole extending along the length direction of each of the portions 21a, 21b.

In other words, in the first portion 21a, the X direction that is the length direction of the first portion 21a is aligned with the length direction of each of the through-holes 20a, whereas in the second portion 21b, the Y direction that is the length direction of the second portion 21b is aligned with the length direction of each of the through-holes 20a.

Although it is not intended to limit the arrangement of the through-holes 20a to this embodiment, in the arrangement of the through-holes 20a of this embodiment, as shown in FIG. 2, a plurality of rows of through-holes 20a are arranged along the length direction of the portion where the through-holes 20a are formed and the through-holes 20a of the respective neighboring rows are arranged in a staggered configuration.

Next, the benefits of this arrangement of the through-holes of this embodiment will be described.

In the angular velocity sensor 100 of this embodiment, the moving part released on the support substrate 1a, as described above, is displaced in the horizontal plane, that is, in the X-Y plane in FIG. 1, along the surface of the other silicon substrate 1b, that is, the semiconductor layer 1b, constructing the moving part 20.

Here, when the plurality of through-holes 20a are formed in the moving part 20, as described above, the moving part 20 having its strength reduced by the through-holes 20a is easily deformed in the vertical direction, that is, in the direction of thickness of the semiconductor layer 1b by the effect of the gravity and the like.

Hence, at the time of forming the plurality of through-holes shaped like a slender hole such as rectangle in the moving part, the present inventors studied a variety of directions of arrangement of the through-holes to lessen a reduction in the strength of the moving part 20 in the direction of thickness of the semiconductor layer 1b to the minimum.

To be more specific, the inventors investigated by use of model analysis using FEM (finite-element method) how much the displacement of the moving part 20 in the direction of thickness of the semiconductor layer 1b was when the direction of arrangement of the through-holes was changed while a predetermined external force was applied to the moving part 20 in the direction of thickness of the semiconductor layer 1b. One example of the analysis is shown.

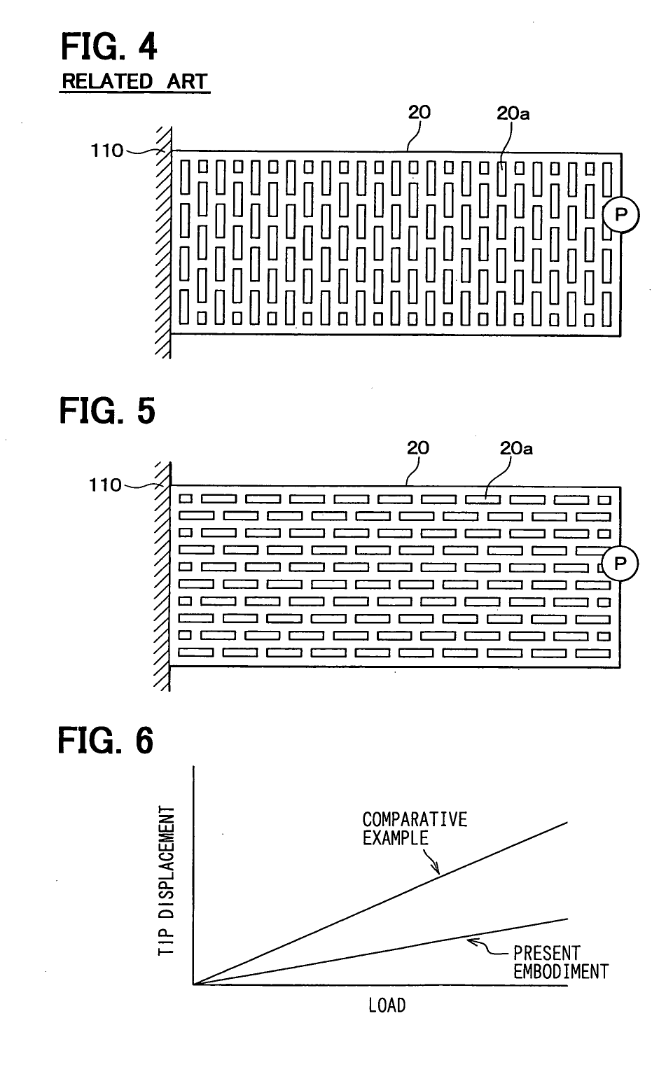

FIG. 4 is an illustration of a model for a comparative example in which the through-holes are arranged so that the length direction of the moving part 20 is perpendicular to the length direction of the through-hole 20a. Further, FIG. 5 is an illustration of a model according to the present embodiment in which the length direction of the moving part 20 is aligned with the length direction of the through-hole 20a.

In FIG. 4 and FIG. 5, the moving part 20 is in a state where one end in the length direction of the moving part 20 is fixedly supported by a support part 110 and where the remaining portion is floated, that is, in a state the moving part 20 is cantilevered.

Displacement at a point P of the other end portion in the length direction of the moving part 20 was found as the displacement of the moving part 20 in the direction of thickness of the semiconductor layer 1b. In other words, the displacement at this point P means the amount of displacement in the direction vertical to the surface of paper in FIG. 4 and FIG. 5 when an external force is applied to the moving part 20 in the vertical direction.

FIG. 6 is a graph to show analysis results in FIG. 4 and FIG. 5 and shows a change in the amount of displacement at the point P, that is, the amount of displacement of a tip when the external force, that is, load applied to the moving part 20 is changed in the comparative example shown in FIG. 4 and in this embodiment shown in FIG. 5. In FIG. 6, both of the longitudinal axis and the lateral axis have arbitrary units.

As shown in this FIG. 6, when the through-holes 20a are arranged in such a way that the length direction of the through-hole 20a is aligned with the length direction of the moving part 20, the amount of displacement of the moving part 20 in the direction of thickness of the semiconductor layer 1b is greatly decreased as compared with a case where the length direction of the through-hole 20a is perpendicular to the length direction of the moving part 20.

That is, it was found that the strength of the moving part 20 in the direction of thickness of the semiconductor layer 1b was greatly increased as compared with the comparative example shown in FIG. 4. From this finding, in this embodiment is adopted the above-described arrangement of the through-holes 20a.

According to this embodiment, there is provided the angular velocity sensor 100 in which the other silicon substrate 1b as the semiconductor layer supported by one silicon substrate 1a as the support substrate is etched to form the moving part 20 released from the one silicon substrate 1aand in which the plurality of through-holes 20a are formed in the moving part 20. The angular velocity sensor 100 is characterized in that the moving part 20 has the plurality of portions 21a and 21b extending in the directions different from each other and in that each of the plurality of through-holes 20a is shaped like a slender hole extending along the length direction of each of the portions 21a and 21b in each of the plurality of portions 21a and 21b of the moving part 20.

When the moving part 20 has the plurality of portions 21a and 21b extending in the directions different from each other, when each of the plurality of through-holes 20a is shaped like a slender hole extending along the length direction of each of the portions 21a and 21b in each of the plurality of portions 21a and 21b of the moving part 20, in each of the plurality of portions 21a and 21b of the moving part 20, there is provided the arrangement of the through-holes 20a in which the length direction of each of the portions 21a and 21b is aligned with the length direction of through-hole 20a in each of the plurality of portions 21a and 21b of the moving part 20.

Hence, according to this embodiment, in the angular velocity sensor 100 in which the semiconductor substrate 1b supported by one support substrate 1ais etched to form the moving part 20 released from the support substrate 1aand in which the plurality of through-holes 20a are formed in the moving part 20, it is possible to lessen a reduction in the strength of the moving part 20 in the direction of thickness of the semiconductor layer 1b to a minimum.

In this regard, when the moving part 20 has the plurality of portions 21a and 21b extending in the directions different from each other, when the plurality of portions 21a and 21b are made identical in the length direction of the through-hole 20a, there are caused portions where the through-holes 20a can not be arranged in such a way as to lessen the reduction in the strength. That is, there are caused portions where the through-holes 20a are forcibly arranged in such a way as to reduce the strength of the moving part 20 comparatively as shown in the comparative example in FIG. 4.

In this embodiment, in consideration of such circumstances, in each of the plurality of portions 21a and 21b extending in the directions different from each other, the through-holes 20a are arranged in such a way that the length direction of each of the portions 21a and 21b is aligned with the length direction of the through-hole 20a to secure uniform excellent strength in each of the plurality of portions 21a and 21b, which can lessen the reduction in the strength of the whole moving part 20 as described above.

### Other Embodiment

In the example shown in FIG. 2, in each of the first portion 21a and the second portion 21b in the frame part 21 of the moving part 20, the length direction of each of the portions 21a and 21b is aligned with the length direction of all of the through-holes 20a.

However, it is not necessarily required that the length direction of each of the portions 21a and 21b be aligned with the length direction of all of the through-holes 20a but, for example, in FIG. 2, the length direction of a part of through-holes 20a in the first portion 21a may point in the Y direction. Similarly, in FIG. 2, the length direction of a part of through-holes 20a in the second portion 21b may point in the X direction.

When the length direction of a part of the through-holes 20a is aligned in this manner with the length direction of a portion where the through-holes 20a are formed, it is possible to lessen a reduction in strength of the moving part 20 in the direction of thickness of the semiconductor layer 1b. Of course, as shown in FIG. 2, it is more preferable from a viewpoint of securing strength that all of the through-holes 20a are aligned with each other in the length direction.

Further, the shapes of the individual through-holes 20a can be made identical with that of the conventional one. It is not necessarily required that the shape of the through-hole 20a be rectangular, but it is essential only that the through-hole be slender. For example, the shape of the through-hole 20a may be slightly ellipsoidal.

Still further, while the number of the plurality of portions 21a and 21b extending in the directions different from each other is two in the above embodiment, the number is not necessarily limited to two but may be three or more. In this case, needless to say, in each of the three or more portions, it is necessary to align the length direction of the portion with the length direction of the through-holes 20a.

Still further, in the above-described angular velocity sensor 100, even when there are a plurality of portions extending in the directions different from each other in the weight part 22, which is a part of the moving part 20, or even when there are a plurality of portions extending in the directions different from each other in the electrode weight 31 except for the moving part 20, needless to say, the same arrangement of the through-holes 20a as the frame part 21 can be adopted.

Still further, while the above-described angular velocity sensor 100 is of the surface-worked type in which the other silicon substrate 1b of the SOI substrate 10 as the semiconductor substrate is worked from its surface to form the above-described structural body in the sensor, it is clear that the invention can be also applied to, for example, a sensor of the bottom-worked type in which an opening is formed in the support substrate 1a to release the moving part.

Still further, the invention can be applied not only to the above-described angular velocity sensor but also to a sensor such as an acceleration sensor and pressure sensor and in which a moving part can be displaced in a predetermined direction when a mechanical quantity is applied thereto.

Still further, the invention can be applied not only to the above-described semiconductor mechanical quantity sensor for detecting a mechanical quantity such as angular velocity and acceleration but also to a semiconductor device in which a semiconductor layer supported by a support substrate is etched to form a moving part released from the support substrate and in which a plurality of through-holes are formed in the moving part.

In short, the invention is a semiconductor device having a moving part in which when the moving part having a plurality of portions extending in the directions different from each other, each of the plurality of portions of the moving part is essentially required to have a plurality of through-holes formed in such a way that each hole is formed in the shape elongated along the length direction of each of the plurality of portions and the other portions can be modified in design if necessary.

The description of the invention is merely exemplary in nature and, thus, variations that do not depart from the gist of the invention are intended to be within the scope of the invention. Such variations are not to be regarded as a departure from the spirit and scope of the invention.

1. A semiconductor device in which a semiconductor layer supported by a support substrate is etched to form a moving part released from the support substrate and in which a plurality of through-holes are formed in the moving part,
wherein the moving part has a plurality of portions extending in directions different from each other, and
wherein each of the plurality of through-holes is formed in a slender hole elongated along a length direction of each of the portions in each of the plurality of portions.

2. The semiconductor device as claimed in claim 1, wherein the moving part can be displaced in a predetermined direction when a mechanical quantity is applied thereto.
